(19) United States
(12) Patent Application Publication
(10) Pub. No.: US 2011/0281443 A1
(43) Pub. Date: Nov. 17, 2011

(54) FILM FORMATION METHOD AND FILM FORMATION APPARATUS

(75) Inventors: Pao-Hwa CHOU, Nirasaki City (JP); Kota UMEZAWA, Nirasaki City (JP); Yosuke WATANABE, Nirasaki City (JP); Masayuki HASEGAWA, Oshu-shi (JP)

(73) Assignee: TOKYO ELECTRON LIMITED, Tokyo (JP)

(21) Appl. No.: 13/106,140

(22) Filed: May 12, 2011

(30) Foreign Application Priority Data
May 14, 2010 (JP) 2010-111986

(51) Int. Cl. H01L 21/316; C23C 16/40

(52) U.S. Cl. 438/787; 118/725; 257/E21.282

(57) ABSTRACT

The film formation method includes transferring an object to be processed into a process chamber; controlling a temperature of the object to be processed to be equal to or lower than 350° C.; and supplying an aminosilane gas as a Si source gas and an oxidizing gas into the process chamber, wherein the oxidizing gas consists of a first oxidizing gas comprising at least one selected from the group consisting of an O₂ gas and an O₃ gas, and a second oxidizing gas comprising at least one selected from the group consisting of a H₂O gas and a H₂O₂ gas, thereby forming a silicon oxide film on a surface of the object to be processed.

### CROSS-REFERENCE TO RELATED PATENT APPLICATIONS

This application claims the benefit of Japanese Patent Application No. 2010-111986, filed on May 14, 2010 in the Japan Patent Office, the disclosure of which is incorporated herein in its entirety by reference.

### BACKGROUND OF THE INVENTION

1. Field of the Invention

The present invention relates to a film formation method and a film formation apparatus for forming a silicon oxide film (SiO₂ film) on an object to be processed, such as a semiconductor wafer or the like.

2. Description of the Related Art

A silicon oxide film (SiO₂ film) is often used as a side wall spacer of a sidewall portion of a gate electrode, an offset spacer for LDD ion implantation, or the like in a semiconductor device. In order to form a SiO₂ film, film formation using chemical vapor deposition (CVD) is collectively performed on a plurality of semiconductor wafers in a vertical and batch type heat treatment apparatus.

Recently, as semiconductor devices get smaller and more highly integrated, a gate length is required to be reduced and impurities need to be more strictly prevented from diffusing. Accordingly, film formation at a low temperature is preferred.

As a technology for forming a SiO₂ film at a low temperature, CVD film formation using BTBAS (bis(tertiary butylamino)silane) as a Si source and O₂, O₃, oxygen radicals, or the like as an oxidizing agent is performed (as disclosed in, for example, Patent References 1, 2, 3, and 4). In these Patent References, a film formation temperature, which is from 650 to 700° C. in a conventional art, is equal to or lower than 600° C.

3. Prior Art Reference

(Patent Reference 1) Japanese Patent Laid-Open Publication No. 2001-156063

(Patent Reference 2) Japanese Patent Laid-Open Publication No. 2004-153066

(Patent Reference 3) Japanese Patent Laid-Open Publication No. 2000-77403

(Patent Reference 4) Japanese Patent Laid-Open Publication No. 2008-109903

### SUMMARY OF THE INVENTION

Recently, as a gate length is required to be further reduced, film formation at a much lower temperature is requested. Although it is considered to perform film formation at 350° C. or lower, which is an extremely low temperature, a SiO₂ film obtained by performing CVD at such a low temperature by using BTBAS (bis(tertiary butylamino)silane), O₂ or the like has an extremely large wet etching rate.

A technical purpose of the present invention is to provide a film formation method and a film formation apparatus that can form a silicon oxide film with a wet etching resistance property that is higher than that in a conventional art, in low temperature film formation at 350° C. or lower.

After conducting an investigation how to solve the problems, the present inventors have found that the reason why a wet etching resistance property of a silicon oxide film formed by a conventional method is reduced in low temperature film formation at 350° C. or lower is that amino groups inflow into the film, and have found that the wet etching resistance property can be improved by reducing the amount of amino groups inflown into the film by using a H₂O gas as an oxidizing gas, as well as an O₂ gas used as an oxidizing gas in the conventional method.

According to an aspect of the present invention, there is provided a film formation method for forming a silicon oxide film on a surface of an object to be processed, the film formation method including: transferring the object to be processed into a process chamber; controlling a temperature of the object to be processed to be equal to or lower than 350° C.; and supplying an aminosilane gas as a Si source gas and an oxidizing gas into the process chamber, wherein the oxidizing gas consists of a first oxidizing gas comprising only an oxygen atom, for example, at least one selected from the group consisting of an O₂ gas and an O₃ gas, and a second oxidizing gas comprising oxygen and hydrogen, for example, at least one selected from the group consisting of a H₂O gas and a H₂O₂ gas.

According to another aspect of the present invention, there is provided a film formation apparatus including: a process chamber which has a vertical and cylindrical shape and is capable of maintaining a vacuum state; a holding member which is held in the process chamber and holds an object to be processed in a plurality of stacks; a transfer unit which transfers the holding member from or into the process chamber; a Si source gas supply unit which supplies an aminosilane gas as a Si source gas into the process chamber; an oxidizing gas supply unit which supplies an oxidizing gas consisting of a first oxidizing gas comprising an only oxygen atom, for example, at least one of an O₂ gas and an O₃ gas and a second oxidizing gas comprising oxygen and hydrogen, for example, at least one of a H₂O gas and a H₂O₂ gas into the process chamber; and a temperature controller which controls a temperature of the object to be processed to be equal to or lower than 350° C., wherein the aminosilane gas is supplied from the Si source gas supply unit into the process chamber, and the first oxidizing gas and the second oxidizing gas are supplied from the oxidizing gas supply unit into the process chamber, so as to form a silicon oxide film on a surface of the object to be processed by using CVD.

Additional objects and advantages of the invention will be set forth in the description which follows, and in part will be obvious from the description, or may be learned by practice of the invention.

The objects and advantages of the invention may be realized and obtained by means of the instrumentalities and combinations particularly pointed out hereinafter.

### BRIEF DESCRIPTION OF THE DRAWINGS

The accompanying drawings, which are incorporated in and constitute a part of the specification, illustrate embodiments of the invention, and together with the general description given above and the detailed description of the embodiments given below, serve to explain the principles of the invention.

FIG. 1 is a longitudinal-sectional view showing a film formation apparatus for performing a film formation method according to an embodiment of the present invention;

FIG. 2 is a cross-sectional view showing the film formation apparatus for performing the film formation method according to the embodiment of the present invention;

FIG. 3 is a graph showing a relationship between a temperature and a wet etching resistance property of a SiO₂ film in a case where only an O₂ gas is used as an oxidizing gas and a case where an O₂ gas and a H₂O gas are used as an oxidizing gas;

FIG. 4 is a graph showing a relationship between a temperature and a density of a SiO₂ film in a case where only an O₂ gas is used as an oxidizing gas and a case where an O₂ gas and a H₂O gas are used as an oxidizing gas; and

FIGS. 5A through 5C are graphs showing relationships between a temperature and concentrations of H, N, and C in a SiO₂ film in a case where only an O₂ gas is used as an oxidizing gas and a case where an O₂ gas and a H₂O gas are used as an oxidizing gas.

### DETAILED DESCRIPTION OF THE INVENTION

An embodiment of the present invention achieved on the basis of the findings given above will now be described with reference to the accompanying drawings. In the following description, the constituent elements having substantially the same function and arrangement are denoted by the same reference numerals, and a repetitive description will be made only when necessary.

The present invention will now be described more fully with reference to the accompanying drawings, in which exemplary embodiments of the invention are shown.

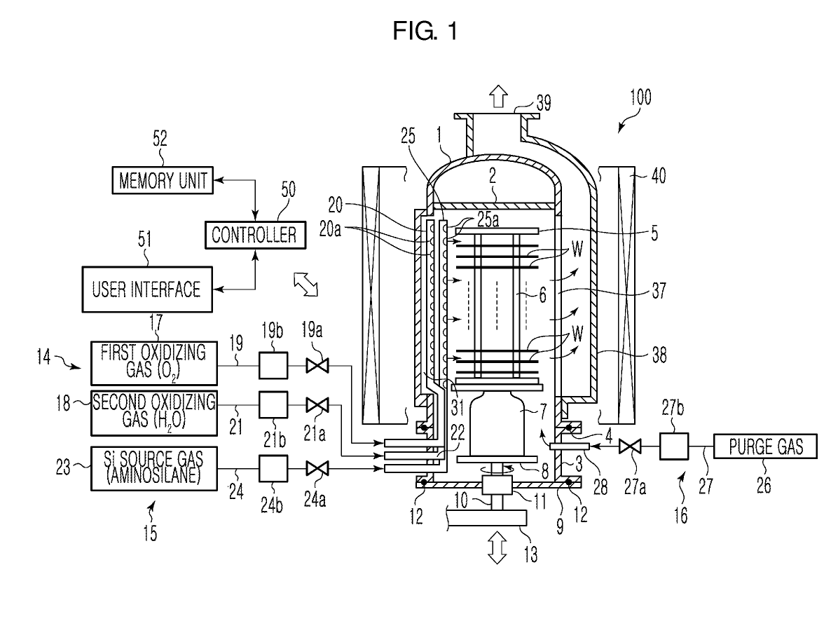

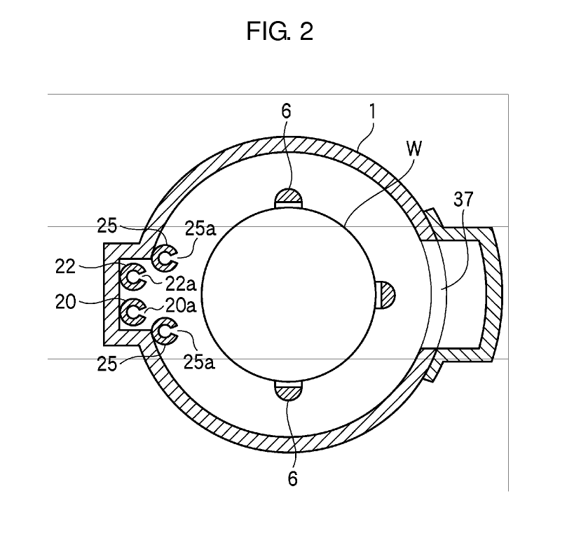

FIG. 1 is a longitudinal-sectional view showing a film formation apparatus for performing a film formation method according to an embodiment of the present invention. FIG. 2 is a cross-sectional view showing the film formation apparatus of FIG. 1. Also, in FIG. 2, a heater is not shown.

A film formation apparatus 100 includes a process chamber 1 having a cylindrical shape whose lower end is opened and whose upper portion is closed. The process chamber 1 is entirely formed of, for example, quartz, and a top plate 2 formed of quartz is provided on an upper end portion in the process chamber 1 so that the process chamber 1 is sealed. Also, a manifold 3 formed of, for example, stainless steel, and having a cylindrical shape is connected to an opening of the lower end of the process chamber 1 with a sealing member 4, such as an O-ring or the like, therebetween.

The manifold 3 supports the lower end of the process chamber 1. A wafer boat 5 formed of quartz and allowing a plurality, for example, from 50 to 100, of semiconductor wafers W as objects to be processed to be stacked in a multistage manner is provided to be inserted from a lower side of the manifold 3 into the process chamber 1. The wafer boat 5 includes three pillars 6 (see FIG. 2), and the plurality of semiconductor wafers W are supported in grooves provided in the pillars 6.

The wafer boat 5 is held on a table 8 with a thermo-container 7 formed of quartz therebetween. The table 8 is supported on a rotation shaft 10 that penetrates through a cover 9 formed of, for example, stainless steel, and used to open and close an opening of a lower end of the manifold 3.

And, for example, a magnetic fluid seal 11 is provided in a penetration portion of the rotation shaft 10, to hermetically seal the rotation shaft 10 and rotatably support the rotation shaft 10. Also, a seal member 12, such as an O-ring, is interposed between a peripheral portion of the cover 9 and a lower end portion of the manifold 3, to seal an inside of the process chamber 1.

The rotation shaft 10 is attached to a leading end of an arm 13 supported by an elevating unit (not shown), for example, a boat elevator or the like, and collectively elevates the wafer boat 5, the cover 9 or the like to be inserted to and to be pulled out from the process chamber 1. Also, the table 8 may be fixedly installed on a side of the cover 9, so that the semiconductor wafers W may be processed without rotating the wafer boat 5.

Also, the film formation apparatus 100 includes an oxidizing gas supply unit 14 for supplying an oxidizing gas into the process chamber 1, a Si source gas supply unit 15 for supplying an aminosilane gas, for example, BTBAS (bis(tertiary butyl-amino)silane), as a Si source gas, into the process chamber 1, and a purge gas supply unit 16 for supplying an inert gas, for example, a N₂ gas, as a purge gas, into the process chamber 1.

The oxidizing gas supply unit 14 includes a first oxidizing gas supply source 17 for supplying a first oxidizing gas (for example, an O₂ gas), and a second oxidizing gas supply source 18 for supplying a second oxidizing gas (for example, a H₂O gas). A first oxidizing gas pipe 19 for guiding the first oxidizing gas is connected to the first oxidizing gas supply source 17, and a first oxidizing gas distribution nozzle 20, for example, a quartz pipe, that penetrates through a sidewall of the manifold 3, is bent upward and vertically extends, is connected to the first oxidizing gas pipe 19. Also, a second oxidizing gas pipe 21 for guiding the second oxidizing gas is connected to the second oxidizing gas supply source 18, and a second oxidizing gas distribution nozzle 22, for example, a quartz pipe, that penetrates through the sidewall of the manifold 3, is bent upward and vertically extends, is connected to the second oxidizing gas pipe 21. A vertical portion of the first oxidizing gas distribution nozzle 20 and a vertical portion of the second oxidizing gas distribution nozzle 22 are held in a recess portion 31 vertically provided in the process chamber 1. And, a plurality of gas ejecting holes 20a and 22a are provided in each of the vertical portions of the first oxidizing gas distribution nozzle 20 and the second oxidizing gas distribution nozzle 22 at predetermined intervals. The first oxidizing gas, for example, an O₂ gas, is ejected substantially uniformly toward the semiconductor wafers W horizontally from each of the gas ejecting holes 20a, and the second oxidizing gas, for example, a H₂O gas, is substantially uniformly ejected toward the semiconductor wafers W horizontally from each of the gas ejecting holes 22a. Also, the first oxidizing gas and the second oxidizing gas may be combined in one distribution injector in the process chamber 1.

Also, the Si source gas supply unit 15 includes a Si source gas supply source 23, a Si source gas pipe 24 for guiding the Si source gas from the Si source gas supply source 23, and a Si source gas distribution nozzle 25 connected to the Si source gas pipe 24, for example, a quartz pipe, that penetrates through the sidewall of the manifold 3, is bent upward and vertically extends. Here, two Si source gas distribution nozzles 25 are installed with the recess portion 31 therebetween (see FIG. 2), and a plurality of gas ejecting holes 25a are provided along longitudinal directions of the source gas distribution nozzles 25 at predetermined intervals in each of the Si source gas distribution nozzles 25. An aminosilane gas, for example, a BTBAS gas, is ejected as the Si source gas substantially uniformly toward the semiconductor wafers W horizontally from each of the gas ejecting holes 25a. Also, the amount of Si source gas distribution nozzles 25 may be 1.

Also, the purge gas supply unit 16 includes a purge gas supply source 26, a purge gas pipe 27 for guiding the purge gas from the purge gas supply source 26, and a purge gas nozzle 28 connected to the purge gas pipe 27 and installed to penetrate a sidewall of the manifold 3. An inert gas, for example, a N₂ gas, may be appropriately used as the purge gas.

Opening/closing valves 19a, 21a, 24a, and 27a and flow rate controllers 19b, 21b, 24b, and 27b, such as mass flow controllers, are installed in the first oxidizing gas pipe 19, the second oxidizing gas pipe 21, the Si source gas pipe 24, and the purge gas pipe 27, respectively, to supply the first oxidizing gas, the second oxidizing gas, the Si source gas, and the purge gas at controlled flow rates.

Meanwhile, an exhaust port 37 for performing vacuum exhaust of an inner space of the process chamber 1 is installed at a portion opposite to the recess portion 31 of the process chamber 1. The exhaust port 37 is longitudinally and narrowly provided by vertically cutting off a sidewall of the process chamber 1. A member 38 covering the exhaust port having an U-shaped cross-section and provided to cover the exhaust port 37 is attached to a portion corresponding to the exhaust port 37 of the process chamber 1. The member 38 covering the exhaust port upwardly extends along the sidewall of the process chamber 1 to define a gas outlet 39 in an upper portion of the process chamber 1. And, vacuum suction is performed from the gas outlet 39 by using a vacuum exhauster including a vacuum pump (not shown) or the like. And, a heater 40 having a cylindrical shape and used to heat the process chamber 1 and the semiconductor wafers W in the process chamber 1 is installed to surround an outer circumference of the process chamber 1. Also, a temperature sensor (not shown), such as a thermocouple or the like, is installed at a predetermined position near the wafer boat 5, to control temperatures of the semiconductor wafers W.

Each element of the film formation apparatus 100 is controlled by a controller 50 including, for example, a microprocessor (computer). For example, the controller 50 controls supply or cutting off of each gas by opening or closing the opening/closing valves 19a, 21a, 24a, and 27a, controls each gas flow rate by using the mass flow controllers 19b, 21b, 24b, and 27b, controls exhaust by using the vacuum exhauster, and controls the temperatures of the semiconductor wafers W by using the heater 40. That is, the controller 50 functions as a gas supply controller, a temperature controller or the like. A user interface 51 including a keyboard by which a command is input in order for an operator to manage the film formation apparatus 100, a display that visibly displays an operation state of the film formation apparatus 100, or the like is connected to the controller 50.

Also, a memory unit 52 contains a control program for accomplishing various processes executed in the film formation apparatus 100 under the control of the controller 50, or a program, that is, a recipe, for executing a process in each element of the film formation apparatus 100 according to process conditions, and is connected to the controller 50. The recipe is stored in a storage medium in the memory unit 52. The storage medium may be a hard disk or a semiconductor memory, or a portable type medium, such as a CDROM, a DVD, a flash memory, or the like. Also, the recipe may be appropriately transmitted from another device via, for example, a dedicated line.

And, if necessary, by invoking an arbitrary recipe according to an instruction or the like from the user interface 51 from the memory unit 52 and executing the recipe in the controller 50, a desired process is executed in the film formation apparatus 100 under the control of the controller 50.

Next, a method for forming a SiO₂ film according to an embodiment of the present invention performed by using the film formation apparatus constructed as described above will be explained.

First, the wafer boat 5 on which, for example, 50 to 100 semiconductor wafers W are mounted as objects to be processed, is raised upwardly to be loaded in the process chamber 1, which is previously controlled to a predetermined temperature, and the opening of the lower end of the manifold 3 is closed by the cover 9, to seal the inside of the process chamber 1. Although the semiconductor wafers W having diameters of 300 mm are given as example, the present embodiment is not limited thereto.

And, vacuum suction is performed in the process chamber 1 such that the process chamber 1 is maintained in a predetermined depressurization atmosphere, power supplied to the heater 40 is controlled, temperatures of the semiconductor wafers are increased to a process temperature and are maintained at the process temperature, and then film formation is started in a state where the wafer boat 5 is rotated.

During the film formation, an aminosilane gas, for example, BTBAS, which is a Si source gas, is supplied from the Si source gas supply source 23 of the Si source gas supply unit 15 via the Si source gas pipe 24 and the Si source gas distribution nozzle 25 into the process chamber 1, a first oxidizing gas, for example, an O₂ gas, is supplied from the first oxidizing gas supply source 17 of the oxidizing gas supply unit 14 via the first oxidizing gas pipe 19 and the first oxidizing gas distribution nozzle 20 into the process chamber 1, and a second oxidizing gas, for example, a H₂O gas, is supplied from the second oxidizing gas supply source 18 via the second oxidizing gas pipe 21 and the second oxidizing gas distribution nozzle 22 into the process chamber 1, to form a silicon oxide film (SiO₂ film) by using CVD. A film formation temperature is a low temperature equal to or lower than 350° C.

Conventionally, a silicon oxide film (SiO₂ film) is formed by using CVD using BTBAS, which is an aminosilane gas, as a Si source gas and only an O₂ gas as an oxidizing gas. However, it is found that when film formation is performed at a low temperature equal to or lower than 350° C. by using the gases, a wet etching resistance property is reduced. The reduction of the wet etching resistance property seems to occur due to inflow of amino groups into a film by using aminosilane gas during film formation.

Since an oxidizing gas is required to have a high oxidizing power, an O₂ gas is conventionally used as such a gas having the high oxidizing power. However, it is found that although an ability of an O₂ gas to oxidize Si in an aminosilane gas is high, an ability of an O₂ gas to oxidize and decompose amino groups is low. Accordingly, if only an O₂ gas is used as an oxidizing gas, amino groups inflow into a film.

In order to oxidize and decompose amino groups, it is effective to use an oxidizing gas comprising H, such as H₂O. However, an ability to oxidize Si by using only H₂O is low.

Accordingly, in the present embodiment, an O₂ gas, as a first oxidizing gas, and a H₂O gas, as a second oxidizing gas, are typically used as an oxidizing gas. An O₃ gas may be used as the first oxidizing gas. Also, a H₂O₂ gas, which is another oxidizing gas comprising H, may be used as the second oxidizing gas. Accordingly, the first oxidizing gas may be at least one selected from the O₂ gas and the O₃ gas, and the second oxidizing gas may be at least one selected from the H₂O gas and the H₂O₂ gas. However, an oxidizing gas is not limited thereto, an oxidizing gas comprising only an oxygen atom may be used as the first oxidizing gas, and an oxidizing gas comprising oxygen and hydrogen may be used as the second oxidizing gas.

An aminosilane gas as the Si source gas is not limited to BTBAS, and another aminosilane gas, for example, tri(dimethylamino)silane (3DMAS), tetra(dimethylamino)silane (4DMAS), diisopropylaminosilane (DIPAS), bis(diethylamino)silane (BDEAS), bis(dimethylamino)silane (BDMAS), or the like may be used.

During film formation, a flow rate of the Si source gas may range from 0.05 to 1 l/min (slm), a flow rate of the first oxidizing gas may range from 0.05 to 10 l/min (slm), and a flow rate of the second oxidizing gas may range from 0.05 to 10 l/min (slm). Also, it is preferable that a pressure in the process chamber ranges from 27 to 1333 Pa (0.2 to 10 Torr). It is preferable that a flow rate ratio (the flow rate of the Si source gas/the flow rate of the oxidizing gases) between the Si source gas and the oxidizing gases (the first oxidizing gas+the second oxidizing gas) ranges from 0.01 to 10. Also, it is preferable that a flow rate ratio between the first oxidizing gas and the second oxidizing gas (the flow rate of the first oxidizing gas/the flow rate of the second oxidizing gas) ranges from 0.01 to 10.

A film formation temperature is equal to or lower than 350° C. as described above, and film formation may be performed at room temperature. A more preferable film formation temperature ranges from 250 to 350° C.

After the film formation ends, vacuum suction is performed in the process chamber 1, a purge gas, for example, a N₂ gas, is supplied from the purge gas supply source 26 via the purge gas pipe 27 and the purge gas nozzle 28 into the process chamber 1 to purge an inner space of the process chamber 1, and then a pressure in the process chamber 1 is returned to a normal pressure to exchange the wafer boat 5.

When compared with conventional film formation using an aminosilane gas and an O₂ gas, a silicon oxide film (SiO₂ film) formed in this way reduces the amount of amino groups inflown into the film to increase a density of the film, thereby improving a wet etching resistance property.

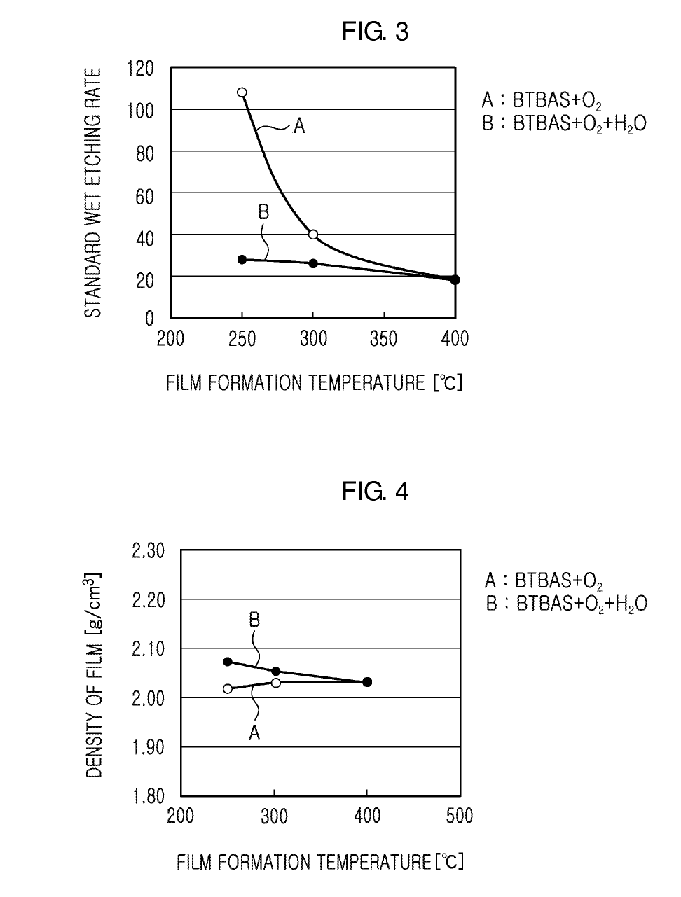

A result of an experiment confirming the above fact will be explained with reference to FIGS. 3 through 5.

First, a wet etching resistance property of a SiO₂ film formed by changing a temperature in a case A where only an O₂ gas is used as an oxidizing gas and a case B where the O₂ gas and a H₂O gas are used as an oxidizing gas when a Si source is fixed to BTBAS was checked.

A result is shown in FIG. 3. FIG. 3 is a graph showing a relationship between a temperature and a wet etching resistance property in the case A and in the case B, wherein a horizontal axis represents a film formation temperature, and a vertical axis represents a standard wet etching rate due to a diluted hydrofluoric acid (100:1DHF) as a solution used in wet etching. Also, the standard wet etching rate is a value corresponding to when an etching rate of a thermal oxide film due to a diluted hydrofluoric acid (100:1DHF) is 1. Also, in the case B, a flow rate ratio (the flow rate of the O₂ gas/the flow rate of the H₂O gas) between the O₂ gas and the H₂O gas is 0.6.

As shown in FIG. 3, in the case A where only the O₂ gas is used as an oxidizing gas, an etching rate is rapidly increased when a film formation temperature is lowered below 350° C., whereas in the case B where the O₂ gas and the H₂O gas are used as an oxidizing gas, an etching rate is barely decreased even when a film formation temperature is lowered. When a film formation temperature is 300° C., an etching rate due to a diluted hydrofluoric acid is 38.6 times with respect to the thermal oxide film in the case A where only the O₂ gas is used as an oxidizing gas and is improved to 26.2 times in the case B. When a film formation temperature is 250° C., an etching rate due to a diluted hydrofluoric acid is 107.8 times in the case A where only the O₂ gas is used as an oxidizing gas and is much improved to 28.1 times in the case B. In this regard, a wet etching resistance property when both of the O₂ gas and the H₂O gas are used as an oxidizing gas is higher than that when only the O₂ gas is used as an oxidizing gas.

Next, a density of a SiO₂ film formed by using the oxidizing gases in the case A and the case B and changing a temperature was checked. A result is shown in FIG. 4. FIG. 4 is a graph showing a relationship between a temperature and a density in the case A and in the case B, wherein a horizontal axis represents a film formation temperature and a vertical axis represents a density of a film.

As shown in FIG. 4, in the case A where only the O₂ gas is used as an oxidizing gas, a density of a film is reduced as a film formation temperature is reduced. However, in the case B where the O₂ gas and the H₂O gas are used as an oxidizing gas, even when a film formation temperature is reduced, a density of a film is barely reduced and is even increased. At a temperature of 400° C., a density of a film in the case A is almost the same as that in the case B. It is found that at a temperature of 350° C. or lower, a density of a film in the case B where the O₂ gas and the H₂O gas are used is higher than a density of a film in the case A where only the O₂ gas is used, and a density difference between the case A and the case B is increased as a film formation temperature is reduced. In this regard, it is understood that the reason that a wet etching resistance property is increased at a temperature of 350° C. or lower when the O₂ gas and the H₂O gas are used as an oxidizing gas is that a density of a film is increased.

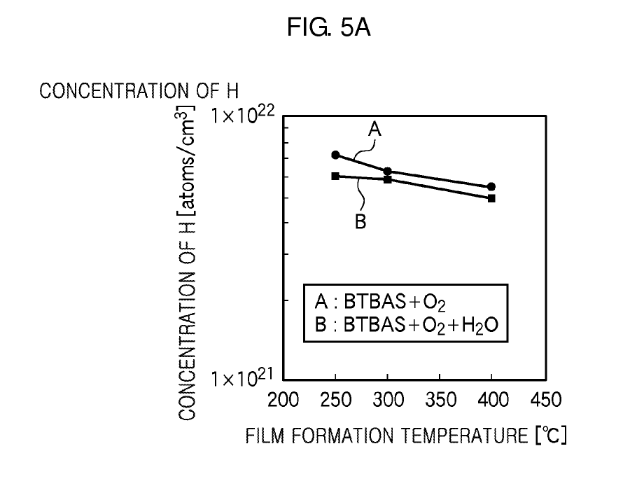

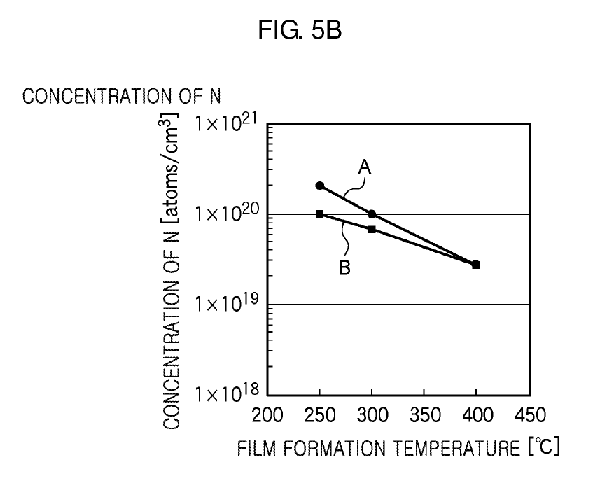

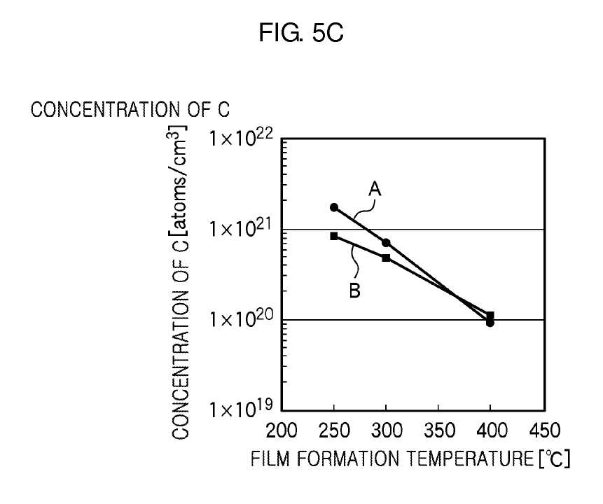

Next, concentrations of H, N, and C constituting amino groups in a film were analyzed by using secondary ion mass spectroscopy (SIMS) in order to know the amount of amino groups inflown into a SiO₂ film formed by using the oxidizing gases of the case A and the case B and changing a temperature. Results are shown in FIGS. 5A through 5C. FIG. 5A shows a relationship between a film formation temperature and a concentration of H in a film, FIG. 5B shows a relationship between the film formation temperature and a concentration of N in the film, and FIG. 5C shows a relationship between the film formation temperature and a concentration of C in the film.

As shown in FIGS. 5A through 5C, it is found that in both the case A where only the O₂ gas is used as an oxidizing gas and the case B where the O₂ gas and the H₂O gas are used as an oxidizing gas, concentrations of H, N, and C constituting amino groups are increased as a film formation temperature is reduced, but an increase in concentrations of H, N, and C constituting amino groups in the case B where the O₂ gas and the H₂O gas are used as an oxidizing gas as a film formation temperature is reduced is lower than an increase in concentrations of H, N, and C constituting amino groups in the case A where only the O₂ gas is used as an oxidizing gas as a film formation temperature is reduced. In this regard, it is found that when an O₂ gas and a H₂O gas are used as an oxidizing gas, at a low temperature film formation at 350° C. or lower, the amount of amino groups inflown into a film is low.

It is found from the experimental results that when an O₂ gas and a H₂O gas are used as an oxidizing gas, the amount of amino groups inflown into a film in low temperature film formation is reduced, a decrease in a density of a film is suppressed, and thus a wet etching resistance property is improved.

Also, the present invention is not limited to the above embodiments, and various modifications may be made. For example, although the present invention is used to a batch type film formation apparatus in which film formation is collectively performed on a plurality of semiconductor wafers in the above embodiments, the present invention is not limited thereto, and the present invention may be used to a single wafer type film formation apparatus in which film formation is performed on a single wafer at a time.

Also, although a SiO₂ film is formed by using thermal CVD in the above embodiments, film formation may be performed by using plasma CVD appropriately generating plasma.

Also, although typical CVD for simultaneously supplying a Si source gas and an oxidizing gas is shown in the above embodiments, a SiO₂ film may be formed by using ALD (Atomic Layer Deposition) in which film formation is performed at an atomic layer level or a molecular layer level by intermittently and alternately supplying a Si source gas and an oxidizing gas. In this case, a first oxidizing gas and a second oxidizing gas may be supplied simultaneously or separately. Also, plasma may be generated when an oxidizing gas is supplied.

And, also, although a semiconductor wafer is used as an object to be processed in the above embodiments, the present invention is not limited thereto, and another substrate, such as an LCD glass substrate or the like, may be used.

According to the present invention, since an aminosilane gas is used as a Si source gas, and a gas consisting of a first oxidizing gas comprising only an oxygen atom, for example, at least one selected from an O₂ gas and an O₃ gas and a second oxidizing gas comprising oxygen and hydrogen, for example, at least one selected from a H₂O gas and a H₂O₂ gas is used as an oxidizing gas, amino groups are oxidized by the second oxidizing gas and thus the amount of amino groups inflown into a film can be reduced, thereby having a wet etching resistance property higher than that in a case where only the first oxidizing gas is used as the oxidizing gas.

What is claimed is:

1. A film formation method for forming a silicon oxide film on a surface of an object to be processed, the film formation method comprising:
transferring the object to be processed into a process chamber;
controlling a temperature of the object to be processed to be equal to or lower than 350° C.; and
supplying an aminosilane gas as a Si source gas and an oxidizing gas into the process chamber,
wherein the oxidizing gas consists of a first oxidizing gas comprising only an oxygen atom and a second oxidizing gas comprising oxygen and hydrogen.

2. The film formation method of claim 1, wherein the first oxidizing gas comprises at least one selected from an O₂ gas and an O₃ gas and the second oxidizing gas comprises at least one selected from a H₂O gas and a H₂O₂ gas.

3. The film formation method of claim 1, wherein a flow rate ratio (a flow rate of the first oxidizing gas/a flow rate of the second oxidizing gas) between the first oxidizing gas and the second oxidizing gas ranges from 0.01 to 10.

4. The film formation method of claim 1, wherein the temperature of the object to be processed ranges from a room temperature to 350° C.

5. The film formation method of claim 4, wherein the temperature of the object to be processed ranges from 250 to 350° C.

6. The film formation method of claim 1, wherein a plurality of the objects to be processed collectively transfer into the process chamber to collectively form the silicon oxide film on the plurality of objects to be processed.

7. A film formation apparatus comprising:
a process chamber which has a vertical and cylindrical shape and is capable of maintaining a vacuum state;
a holding member which holds an object to be processed in a plurality of stacks and is held in the process chamber;
a transfer unit which transfers the holding member from or into the process chamber;
a Si source gas supply unit which supplies an aminosilane gas as a Si source gas into the process chamber;
an oxidizing gas supply unit which supplies an oxidizing gas consisting of a first oxidizing gas comprising only an oxygen atom and a second oxidizing gas comprising oxygen and hydrogen into the process chamber; and
a temperature controller which controls a temperature of the object to be processed to be equal to or lower than 350° C.,
wherein the aminosilane gas is supplied from the Si source gas supply unit into the process chamber, and the first oxidizing gas and the second oxidizing gas are supplied from the oxidizing gas supply unit into the process chamber, so as to form a silicon oxide film on a surface of the object to be processed by using CVD.

8. The film formation apparatus of claim 7, wherein the first oxidizing gas comprises at least one selected from an O₂ gas and an O₃ gas and the second oxidizing gas comprises at least one selected from a H₂O gas and a H₂O₂ gas.

9. The film formation apparatus of claim 7, wherein the oxidizing gas supply unit supplies the first oxidizing gas and the second oxidizing gas at a flow rate ratio (a flow rate of the first oxidizing gas/a flow rate of the second oxidizing gas) ranging from 0.01 to 10.

10. The film formation apparatus of claim 7, wherein the temperature controller controls the temperature of the object to be processed to a range from a room temperature to 350° C.

11. The film formation apparatus of claim 10, wherein the temperature controller controls the temperature of the object to be processed to a range from 250 to 350° C.
